(19) United States
(12) Patent Application Publication
(10) Pub. No.: US 2013/0126215 A1
(43) Pub. Date: May 23, 2013

(54) PRINTED CIRCUIT BOARD AND METHOD FOR MANUFACTURING THE SAME

(71) Applicants: Suk Hyeon Cho, Gyeonggi-do (KR); Francis Sohn, Gyeonggi-do (KR)

(72) Inventors: Suk Hyeon Cho, Gyeonggi-do (KR); Francis Sohn, Gyeonggi-do (KR)

(73) Assignee: SAMSUNG ELECTRO-MECHANICS CO., LTD., Suwon-si (KR)

(21) Appl. No.: 13/489,045

(22) Filed: Jun. 5, 2012

(30) Foreign Application Priority Data
Nov. 22, 2011 (KR) 10-2011-0122346

(51) Int. Cl. H05K 7/20; H05K 3/42

(52) U.S. Cl. 174/252; 29/852

(57) ABSTRACT

The present invention relates to a printed circuit board including: a substrate; a circuit pattern formed on a surface of the substrate; a dummy pattern formed on the surface of the substrate, where the circuit pattern is not formed, to be spaced apart from the circuit pattern by a predetermined interval; and a plurality of heat radiating vias formed along an outer edge of the substrate to electrically connect the dummy patterns through the substrate, and it is possible to suppress generation of electromagnetic waves or shield the electromagnetic waves and improve heat radiating characteristics at the same time.

### CROSS-REFERENCE TO RELATED APPLICATIONS

Claim and incorporate by reference domestic priority application and foreign priority application as follows:

### CROSS REFERENCE TO RELATED APPLICATION

This application claims the benefit under 35 U.S.C. Section 119 of Korean Patent Application Serial No. 10-2011-0122346, entitled filed Nov. 22, 2011, which is hereby incorporated by reference in its entirety into this application.”

### BACKGROUND OF THE INVENTION

1. Field of the Invention

The present invention relates to a printed circuit board and a method for manufacturing the same, and more particularly, to a printed circuit board capable of suppressing generation of electromagnetic waves or shielding electromagnetic waves in a printed circuit board and overcoming heat generation, and a method for manufacturing the same.

2. Description of the Related Art

In recent times, miniaturization and technology integration of electronic devices and products have been steadily developed due to advance of the electronic devices and products. In addition, various changes in a manufacturing process of a printed circuit board (PCB) used in the electronic devices and products are also needed in response to miniaturization and technology integration.

A technical direction for a method of manufacturing a PCB has been developed from a single-sided PCB to a double-sided PCB at an early stage and to a multilayer PCB again. Especially, recently, in manufacturing the multilayer PCB, a manufacturing method, which is called a build-up method, is being developed.

Meanwhile, as development trends of the electronic devices seek for miniaturization and thinning, circuit patterns formed on the PCB become complicated and fine. Due to this, electromagnetic waves are generated from the circuit patterns or electronic components to exert a bad effect on the electronic device or a human body.

Further, there is a problem that a portion in which the electronic component is embedded or portions connected by wire bonding are damaged due to heat generated when the electronic component is driven. Due to this, there is a problem of deterioration of reliability of the printed circuit board.

In order to overcome the above-described problems, in the prior art, a metal tape or a metal plate is attached to a case of the electronic device or between a plurality of electronic components so as to suppress generation of electromagnetic waves or shield electromagnetic waves.

However, an attachment space should be secured in order to attach the metal tape or the metal plate to the case of the electronic device or between the plurality of electronic components, but as the circuit patterns become complicated and fine, it is not easy to select a position for attaching the metal tape or the metal plate. Especially, although the metal tape is attached to the case of the electronic device, since the electronic components inside the electronic device are affected by electromagnetic waves, there is a problem of malfunction of the electronic components due to electromagnetic interference.

Like this, since it is not possible to effectively shield electromagnetic waves, there is a problem of deterioration of reliability of the entire electronic device in which a PCB is installed.

Due to this, in this art, there is a need for a way of suppressing generation of electromagnetic waves or shielding electromagnetic waves in a PCB and overcoming heat generation at the same time.

### SUMMARY OF THE INVENTION

The present invention has been invented in order to overcome the above-described problems and it is, therefore, an object of the present invention to provide a printed circuit board capable of suppressing generation of electromagnetic waves or shielding the electromagnetic waves and improving heat radiation characteristics at the same time by disposing a dummy pattern on a surface of a substrate on which a circuit pattern is not formed, and a method of manufacturing the same

It is another object of the present invention to provide a printed circuit board capable of effectively radiating heat by embedding a dummy pattern in at least one surface of a substrate and forming at least one projection on the embedded dummy pattern, and a method of manufacturing the same.

It is still another object of the present invention to provide a printed circuit board capable of suppressing or shielding electromagnetic waves generated from side surfaces of a substrate and improving heat radiation characteristics at the same time by forming a plurality of heat radiating vias along an outer edge of the substrate.

In accordance with one aspect of the present invention to achieve the object, there is provided a printed circuit board including: a substrate; a circuit pattern formed on a surface of the substrate; a dummy pattern formed on the surface of the substrate, where the circuit pattern is not formed, to be spaced apart from the circuit pattern by a predetermined interval; and a plurality of heat radiating vias formed along an outer edge of the substrate to electrically connect the dummy patterns through the substrate.

The dummy pattern may be embedded in at least one surface of the substrate.

The plurality of heat radiating vias may be formed to be overlapped with each other.

The plurality of heat radiating vias may be formed at intervals smaller than twice the diameter of the heat radiating via.

The dummy pattern may have at least one projection.

The projection may be made of the same material as the dummy pattern and have a shape protruding to the outside.

The projection may be integrally formed with the dummy pattern and have a structure in which an insulating material is filled inside and a metal material is formed on the insulating material.

The surface in which the dummy pattern is embedded may be a surface of the substrate on which an electronic component is mounted.

The printed circuit board may further include a solder resist layer formed on the surface in which the dummy pattern is not embedded.

The solder resist layer may be formed by printing a solder resist ink on the surface in which the dummy pattern is not embedded.

Meanwhile, in accordance with another aspect of the present invention to achieve the object, there is provided a method for manufacturing a printed circuit board including the steps of: providing a substrate; forming a circuit pattern on a surface of the substrate; forming a dummy pattern on the surface of the substrate, where the circuit pattern is not formed, to be spaced apart from the circuit pattern by a predetermined interval; and forming a plurality of heat radiating vias along an outer edge of the substrate to electrically connect the dummy patterns through the substrate.

The step of forming the dummy pattern may form the dummy pattern by embedding the dummy pattern in at least one surface of the substrate.

The circuit pattern may include first and second circuit patterns which are formed on upper and lower surfaces of the substrate, respectively, and the dummy pattern may include first and second dummy patterns which are formed on the upper and lower surfaces of the substrate, respectively.

The step of forming the dummy pattern by embedding the dummy pattern in the at least one surface of the substrate may include the steps of: providing a carrier; forming the second dummy pattern and the second circuit pattern on the carrier; forming the substrate on the second dummy pattern and the second circuit pattern; forming the first dummy pattern and the first circuit pattern on the substrate; and removing the carrier.

The step of forming the dummy pattern by embedding the dummy pattern in the at least one surface of the substrate may form at least one projection on the dummy pattern.

The step of forming the at least one projection on the dummy pattern may include the steps of: providing the carrier having at least one groove formed on one surface thereof; forming the second dummy pattern in correspondence to the at least one groove and forming the second circuit pattern on the carrier; forming the substrate on the second dummy pattern and the second circuit pattern; forming the first dummy pattern and the first circuit pattern on the substrate; and removing the carrier.

The plurality of heat radiating vias may be formed to be overlapped with each other.

The plurality of heat radiating vias may be formed at intervals smaller than twice the diameter of the heat radiating via.

The projection may be made of the same material as the dummy pattern and have a shape protruding to the outside.

The projection may be integrally formed with the dummy pattern and have a structure in which an insulating material is filled inside and a metal material is formed on the insulating material.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a cross-sectional view of a printed circuit board in accordance with an embodiment of the present invention;

FIG. 2 is a cross-sectional view showing a structure in which a circuit pattern and a dummy pattern on an upper surface of a substrate shown in FIG. 1 are embedded;

FIG. 3 is a cross-sectional view showing a structure in which a circuit pattern and a dummy pattern on a lower surface of the substrate shown in FIG. 1 are embedded;

FIG. 4 is a cross-sectional view showing a structure in which a plurality of projections are formed on the dummy pattern shown in FIG. 3;

FIG. 5 is a plan view showing a structure in which a plurality of heat radiating vias are formed in the substrate shown in FIG. 1;

FIG. 6 is a cross-sectional view showing a structure in which a solder resist layer is applied in a printed circuit board shown in FIG. 2;

FIG. 7 is a graph showing thermal resistance varied according to various shapes in which the dummy pattern is formed;

FIGS. 8 to 10 are cross-sectional views showing a process of manufacturing a printed circuit board in accordance with an embodiment of the present invention, wherein FIG. 8 is a cross-sectional view showing a substrate in which a heat radiating via is formed, FIG. 9 is a cross-sectional view showing a circuit pattern formed on a surface of the substrate, and FIG. 10 is a cross-sectional view showing a dummy pattern formed on the surface of the substrate;

FIGS. 11 to 14 are cross-sectional views showing a process of forming the dummy pattern by embedding the dummy pattern in a lower surface of the substrate, wherein FIG. 11 is a cross-sectional view showing a second dummy pattern and a second circuit pattern formed on a carrier, FIG. 12 is a cross-sectional view showing the substrate formed on the second dummy pattern and the second circuit pattern, FIG. 13 is a cross-sectional view showing a first dummy pattern and a first circuit pattern formed on the substrate, and FIG. 14 is a cross-sectional view showing the dummy pattern embedded in the lower surface of the substrate by removing the carrier; and

FIGS. 15 to 19 are cross-sectional views showing a process of forming at least one projection on the dummy pattern, wherein FIG. 15 is a cross-sectional view showing the carrier having at least one groove formed on one surface thereof, FIG. 16 is a cross-sectional view showing the second dummy pattern formed in correspondence to the at least one groove and the second circuit pattern formed on the carrier, FIG. 17 is a cross-sectional view showing the substrate formed on the second dummy pattern and the second circuit pattern, FIG. 18 is a cross-sectional view showing the first dummy pattern and the first circuit pattern formed on the substrate, and FIG. 19 is a cross-sectional view showing the at least one projection formed on the dummy pattern by removing the carrier.

### DETAILED DESCRIPTION OF THE PREFERABLE EMBODIMENTS

The terms or words used in the present specification and claims should not be interpreted as being limited to typical or dictionary meanings, but should be interpreted as having meanings and concepts relevant to the technical spirit of the present invention based on the rule according to which an inventor can appropriately define the concept of the term to describe his/her own invention in the best manner.

Therefore, configurations shown in embodiments and the drawings of the present invention rather are examples of the most exemplary embodiment and do not represent all of the technical spirit of the invention. Thus, it will be understood that various equivalents and modifications that replace the configurations are possible when filing the present application.

Hereinafter, embodiments of the present invention will be described in detail with reference to the accompanying drawings.

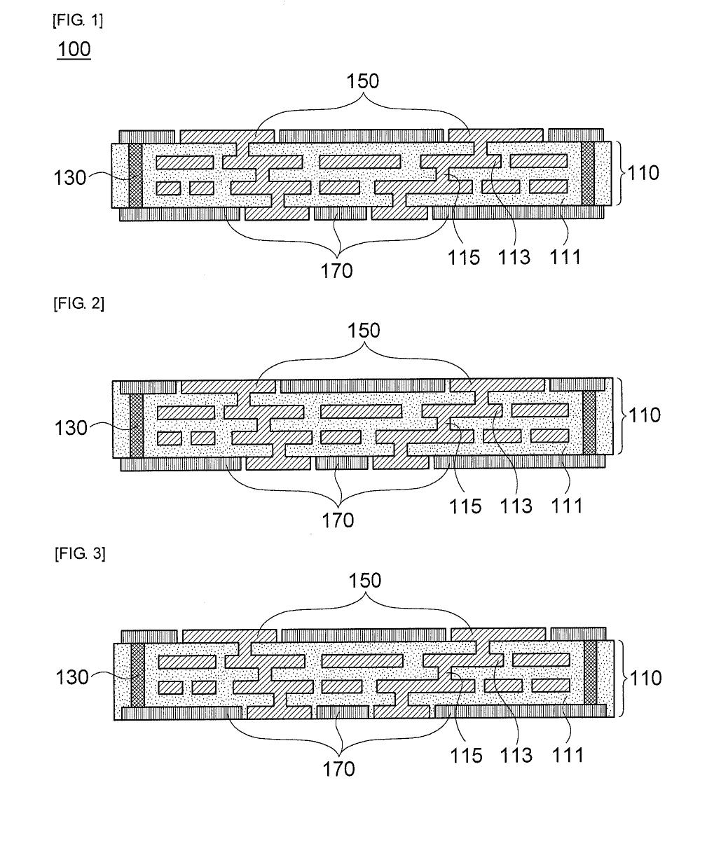

FIG. 1 shows a cross-sectional view of a printed circuit board in accordance with an embodiment of the present invention.

As shown in FIG. 1, a printed circuit board 100 includes a substrate 110, a heat radiating via 130, a circuit pattern 150, and a dummy pattern 170.

The substrate 110 is a means of supporting the printed circuit board 100. When the printed circuit board is a multilayer printed circuit board, the substrate 110 may have a structure in which a plurality of insulators 111 are stacked, an inner layer circuit pattern 113 is formed on one surface of each insulator 111, and a circuit via 115 is formed to electrically connect a plurality of inner layer circuit patterns 113.

At this time, the insulator 111 may be made of a material, which has low electrical conductivity and hardly passes current, such as prepreg, Ajinomoto build-up film (ABF), or epoxy and may use various materials without being limited to the above materials.

Further, the circuit via 115 electrically connects the inner layer circuit pattern 113, the circuit pattern 150, and an electronic component of each layer, and various via holes such as an inner via hole (IVH), a blind via hole (BVH), and a plated through hole (PTH) may be formed to form the circuit via 115.

Meanwhile, configuration of the printed circuit board as in FIG. 1 is only an example. The printed circuit board may be a single-sided printed circuit board, a both-sided printed circuit board, or a multilayer printed circuit board, and technical features of the present invention, which will be described below, can be equally applied.

The heat radiating via 130 is a means which is formed through the substrate 110 and used to electrically connect the dummy patterns 170 on upper and lower surfaces of the substrate 110.

In order to form this heat radiating via 130, first, a reference hole is processed by an X-ray drill or a sensor drill, a through hole is formed in a desired position of the substrate 110 based on the reference hole by a computer numerical control (CNC) drill, and a metal material is filled in the through hole to form the heat radiating via 130.

Further, it is possible to form the heat radiating via 130 after forming the through hole with various laser, which can form a hole, such as ultraviolet (UV) laser or carbon dioxide (CO₂) laser in addition to the X-ray drill and the sensor drill.

The dummy pattern 170 is electrically connected to the heat radiating via 130 and formed on the surface of the substrate 110, where the circuit pattern 150 is not formed, by being spaced apart from the circuit pattern 150 by a predetermined interval so as not to be connected to the circuit pattern 150. At this time, the dummy pattern 170 may be made of a metal material such as copper (Cu), silver (Ag), gold (Au), aluminum (Al), iron (Fe), titanium (Ti), or molybdenum (Mo) and may use various materials without being limited to the above materials.

Further, the dummy pattern 170 may be disposed on the substrate 110 in a plate shape or a mesh structure.

When describing the above-described dummy pattern in more detail, in order to improving heat radiation characteristics in the printed circuit board 100, a metal, which performs a role of radiating heat, should be prepared, and especially, a ratio of volume of the prepared metal should be high. Accordingly, it is possible to improve heat radiation characteristics and obtain an effect of shielding electromagnetic waves at the same time by wholly applying the metal dummy pattern 170 on the remaining region except the region of the substrate 110 in which an electrical connection terminal or the circuit pattern 150 is formed.

Here, the dummy pattern 170 may be formed to be spaced apart from the electrical connection terminal or the circuit pattern 150 by a predetermined interval so as to prevent electrical connection with the electrical connection terminal or the circuit pattern 150.

In addition, since the dummy patterns 170 are formed in large areas of the both surfaces of the substrate 110, it is possible to secure structural stability such as warpage of the substrate 110 by performing a role of a stiffener.

Meanwhile, the dummy pattern 170 is configured not to be directly connected to a ground layer inside the substrate 110. Instead, the dummy pattern 170 may be connected to a terminal or an electronic component of another substrate in contact with the substrate 110.

The reason is to prevent a voltage change of the ground layer due to a voltage change of the dummy pattern 170 which absorbs electromagnetic waves emitted from the inside of the substrate 110 by configuring the dummy pattern 170 not to be directly connected to the ground layer inside the substrate 110.

Due to this, there is an advantage that it is possible to stably operate the electronic component mounted on the substrate 110 by supplying a stable voltage to the electronic component.

FIG. 2 is a cross-sectional view showing a structure in which the circuit pattern and the dummy pattern on the upper surface of the substrate shown in FIG. 1 are embedded, and FIG. 3 is a cross-sectional view showing a structure in which the circuit pattern and the dummy pattern on the lower surface of the substrate shown in FIG. 1 are embedded.

As shown in FIGS. 2 and 3, the printed circuit board 100 may employ a structure in which the circuit pattern 150 and the dummy pattern 170 on the upper surface are embedded in the substrate 110 or the circuit pattern 150 and the dummy pattern 170 on the lower surface are embedded in the substrate 110. That is, the printed circuit board 100 may have a structure in which the circuit pattern 150 and the dummy pattern 170 are embedded in the insulator 111 of the substrate 110, that is, at least one surface of the substrate 110.

As in FIGS. 2 and 3, when employing the structure in which the circuit pattern 150 and the dummy pattern 170 are embedded in the insulator 111, since the insulator 111 performs a role of solder resist as well as a unique role of the insulator 111, there is an advantage that it is not required to additionally form solder resist on a surface of the insulator 111 in which the circuit pattern 150 and the dummy pattern 170 are embedded.

Due to this, since manufacturing costs of the printed circuit are reduced and a thickness of the printed circuit board is reduced compared to a conventional printed circuit board, there is an advantage that miniaturization of the electronic devices can be achieved.

Further, by using the surface, on which the electronic component is mounted, as the surface in which the circuit pattern 150 and the dummy pattern 170 are embedded, it is possible to prevent electromagnetic waves generated from the inside of the printed circuit board 100 from being emitted to the outside due to the dummy pattern 170 and the heat radiating via 130 and effectively prevent generation of a void due to a step when applying a die bond film for attaching the electronic component and the printed circuit board.

FIG. 4 is a cross-sectional view showing a structure in which a plurality of projections are formed on the dummy pattern shown in FIG. 3.

As shown in FIG. 4, the dummy pattern 170 may have at least one projection 172, and the projection 172 may be formed in a shape protruding to the outside such as a cylinder or a cone.

At this time, the projection 172 may be made of a metal material and have a structure in which an insulating material is filled inside and a metal material is formed on the insulating material with a predetermined thickness.

Further, the projection 172 may be made of the same material as the dummy pattern 170 and integrally formed with the dummy pattern 170.

Like this, since the projection 172 is formed in a shape protruding to the outside to increase a surface area for radiating heat, there is an advantage that it is possible to effectively increase heat diffusion compared to the printed circuit board 100 shown in FIG. 1.

Further, when attaching different materials such as solder, since the projection 172 can provide a wide surface area, it can be also used as a terminal for connection with an external substrate.

In addition, since the projection 172 is formed by being plated together when the circuit pattern 150 and the dummy pattern 170 are formed, there is an advantage that a high-cost plating process is not additionally needed.

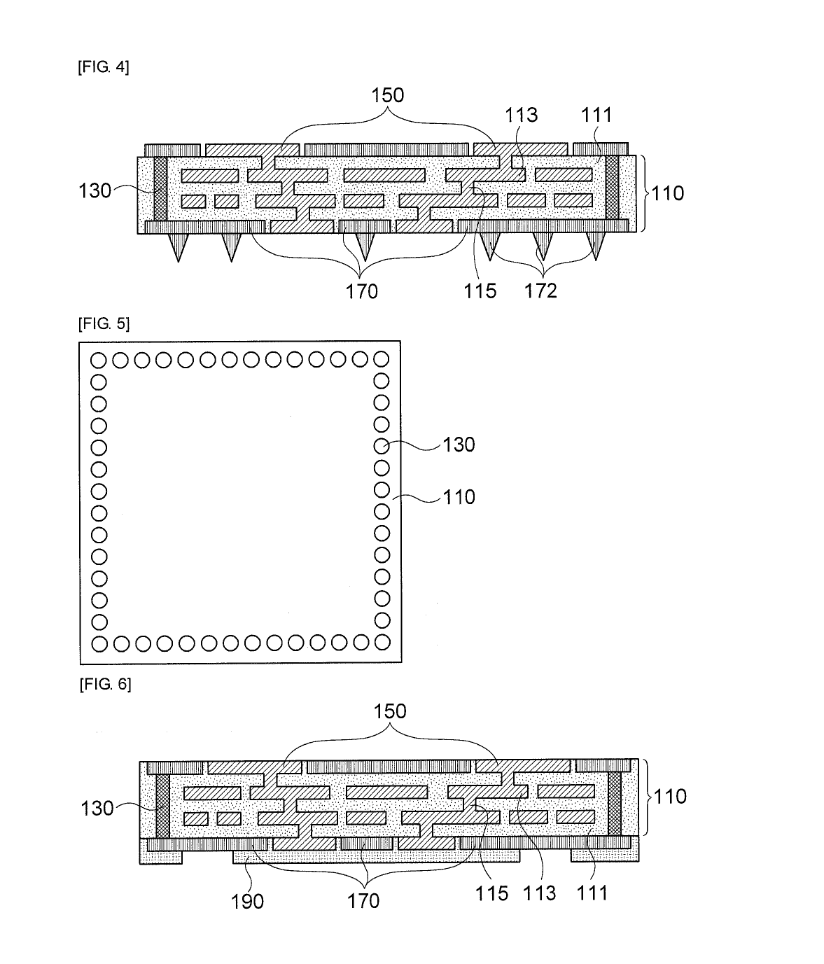

FIG. 5 is a plan view showing a structure in which a plurality of heat radiating vias are formed in the substrate shown in FIG. 1.

Referring to FIG. 5, the plurality of heat radiating vias 130 may be formed along an outer edge of the substrate 110. At this time, in FIG. 5, only a formation structure of the heat radiating via 130 is shown, and structures of other components except the heat radiating via 130 will be omitted.

In FIG. 5, by densely forming the plurality of heat radiating vias 130 along the outer edge of the substrate 110, it is possible to prevent electromagnetic waves from being emitted through side surfaces of the printed circuit board 100 and allow the heat radiating via 130 to perform a role of a thermal via through which heat moves between a plurality of layers.

Further, the plurality of heat radiating vias 130 may be formed at intervals smaller than twice the diameter of the heat radiating via 130 or formed to be overlapped with each other.

Meanwhile, the heat radiating via 130 can be formed in various structures without being limited to the formation structure shown in FIG. 5.

FIG. 6 is a cross-sectional view showing a structure in which a solder resist layer is applied in the printed circuit board shown in FIG. 2.

As shown in FIG. 6, the printed circuit board 100 may further include a solder resist layer 190 formed on the substrate 110 in which the dummy pattern 170 is not embedded.

As described above, when forming the solder resist layer 190 on the surface in which the dummy pattern 170 is not embedded, it is possible to form the solder resist layer 190 using a solder resist ink. That is, it is possible to form the solder resist layer 190 by printing the solder resist ink on the surface in which the dummy pattern 170 is not embedded.

At this time, there is an advantage that it is possible to obtain an effect of shielding electromagnetic waves by using a ferromagnetic material such as ferrite, as a solder resist ink.

In conclusion, it is possible to improve heat radiation characteristics as well as to effectively shield electromagnetic waves with respect to the entire six surfaces of the printed circuit board 100 by applying the dummy patterns 170 on the both surfaces, that is, the upper and lower surfaces of the substrate 110 and forming the heat radiating vias 130 along the outer edge of the substrate 110.

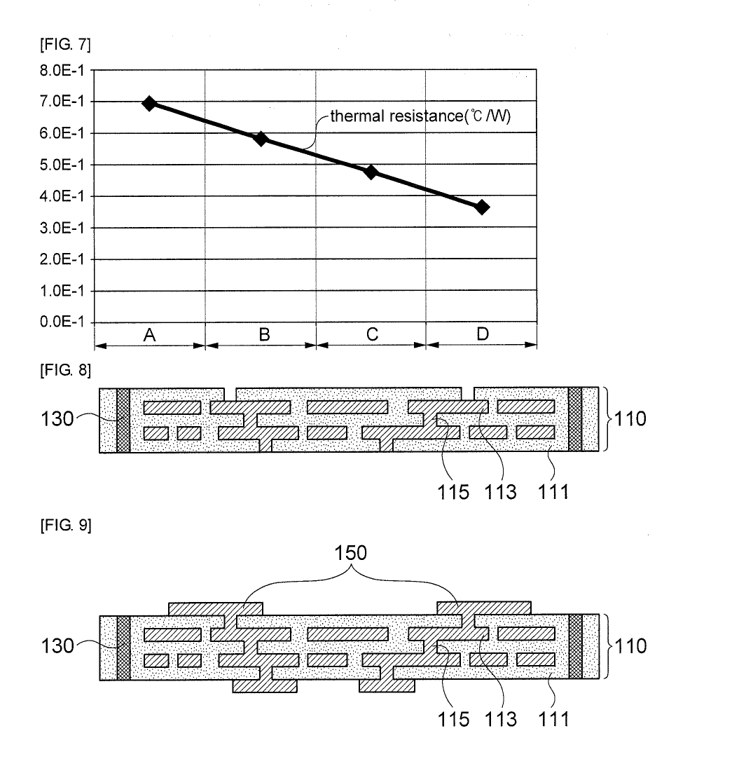

FIG. 7 is a graph showing thermal resistance varied according to various shapes in which the dummy pattern is formed.

In FIG. 7, a represents thermal resistance in a structure in which the dummy pattern is formed on the surface of the substrate, b represents thermal resistance in a structure in which the dummy pattern is embedded in one surface of the substrate, c represents thermal resistance in which the dummy pattern is formed on the surface of the substrate and the projection is formed on the dummy pattern, and d represents thermal resistance in a structure in which the dummy pattern is embedded in one surface of the substrate and the projection is formed on the dummy pattern.

At this time, the printed circuit board used in the test is a four-layered substrate with a thickness of 0.13 t, and heat radiating characteristics in the vertical direction are shown.

Referring to FIG. 7, in case of a, thermal resistance is 6.97E-01(° C./W), in case of b, thermal resistance is 5.85E-01(° C./W), in case of c, thermal resistance is 4.77E-01(° C./W), and in case of d, thermal resistance is 3.65E-01(° C./W). Therefore, it is possible to check that thermal resistance is reduced from the case a to the case d so that a heat radiation effect is improved.

Hereinafter, a process of manufacturing a printed circuit board in accordance with an embodiment of the present invention will be described.

FIGS. 8 to 10 are cross-sectional views showing a process of manufacturing a printed circuit board in accordance with an embodiment of the present invention.

Referring to FIG. 8, a substrate 110 is provided. Here, the substrate 110 is a means of supporting the printed circuit board 100. When the printed circuit board is a multilayer printed circuit board, the substrate 110 may have a structure in which a plurality of insulators 111 are stacked, an inner layer circuit pattern 113 is formed on one surface of each insulator 111, and a circuit via 115 is formed to electrically connect a plurality of inner layer circuit patterns 113.

At this time, the insulator 111 may be made of a material, which has low electrical conductivity and hardly passes current, such as prepreg, Ajinomoto build-up film (ABF), or epoxy and may use various materials without being limited to the above materials.

After that, a heat radiating via 130 is formed through the substrate 110. At this time, by densely forming a plurality of heat radiating vias 130 along an outer edge of the substrate 110, it is possible to prevent electromagnetic waves from being emitted through side surfaces of the printed circuit board 100 and allow the heat radiating via 130 to perform a role of a thermal via through which heat moves between a plurality of layers.

Further, the plurality of heat radiating vias 130 may be formed at intervals smaller than twice the diameter of the heat radiating via 130 or formed to be overlapped with each other.

Next, as in FIG. 9, a circuit pattern 150 is formed on a surface of the substrate 110. At this time, the circuit pattern 150 may consist of a first circuit pattern 150a formed on an upper surface of the substrate 110 and a second circuit pattern 150b formed on a lower surface of the substrate 110.

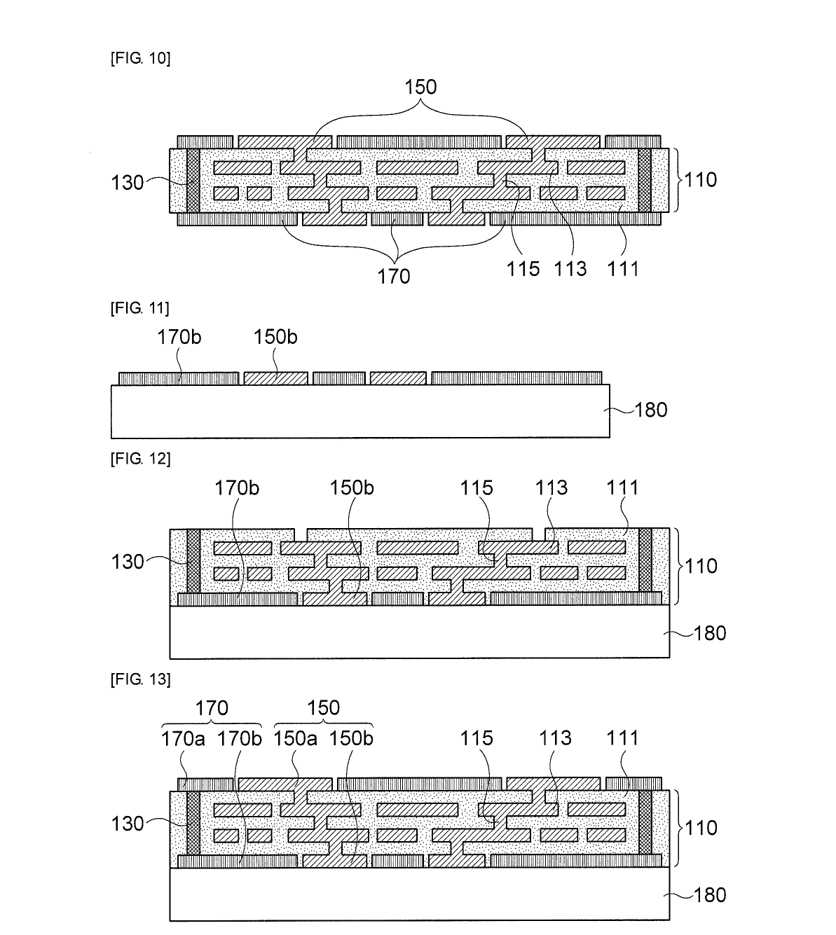

Next, as in FIG. 10, a dummy pattern 170 is formed on the surface of the substrate 110, where the circuit pattern 150 is not formed, to be spaced apart from the circuit pattern 150 by a predetermined interval and electrically connected to the heat radiating via 130.

At this time, the dummy pattern 170 may consist of first and second dummy patterns 170a and 170b which are formed on the upper and lower surfaces of the substrate 110, respectively, and may be made of a metal material such as copper (Cu), silver (Ag), gold (Au), aluminum (Al), iron (Fe), titanium (Ti), or molybdenum (Mo).

Further, the dummy pattern 170 may be disposed on the substrate 110 in a plate shape or a mesh structure.

When describing the above-described dummy pattern in more detail, in order to improving heat radiation characteristics in the printed circuit board 100, a metal, which performs a role of radiating heat, should be prepared, and especially, a ratio of volume of the prepared metal should be high. Accordingly, it is possible to improve heat radiation characteristics and obtain an effect of shielding electromagnetic waves at the same time by wholly applying the metal dummy pattern 170 on the remaining region except the region of the substrate 110 in which an electrical connection terminal or the circuit pattern 150 is formed.

Here, the dummy pattern 170 may be formed to be spaced apart from the electrical connection terminal or the circuit pattern 150 by a predetermined interval so as to prevent electrical connection with the electrical connection terminal or the circuit pattern 150.

In addition, since the dummy patterns 170 are formed in large areas of the both surfaces of the substrate 110, it is possible to secure structural stability such as warpage of the substrate 110 by performing a role of a stiffener.

Meanwhile, the printed circuit board 100 may employ a structure in which the circuit pattern 150 and the dummy pattern 170 on the upper surface are embedded in the substrate 110 or the circuit pattern 150 and the dummy pattern 170 on the lower surface are embedded in the substrate 110. That is, the printed circuit board 100 may have a structure in which the circuit pattern 150 and the dummy pattern 170 may be embedded in the insulator 111 of the substrate 110, that is, at least one surface of the substrate 110.

FIGS. 11 to 14 are cross-sectional views showing a process of forming the dummy pattern by embedding the dummy pattern in the lower surface of the substrate. As shown in FIG. 11, the second dummy pattern 170b and the second circuit pattern 150b are formed on a carrier 180.

After that, as in FIG. 12, the substrate 110 is formed on the first dummy pattern 170b and the second circuit pattern 150b. At this time, the substrate 110 may have a structure in which the plurality of insulators 111 are stacked, the inner layer circuit pattern 113 is formed on one surface of each insulator 111, and the circuit via 115 is formed to electrically connect the plurality of inner layer circuit patterns 113.

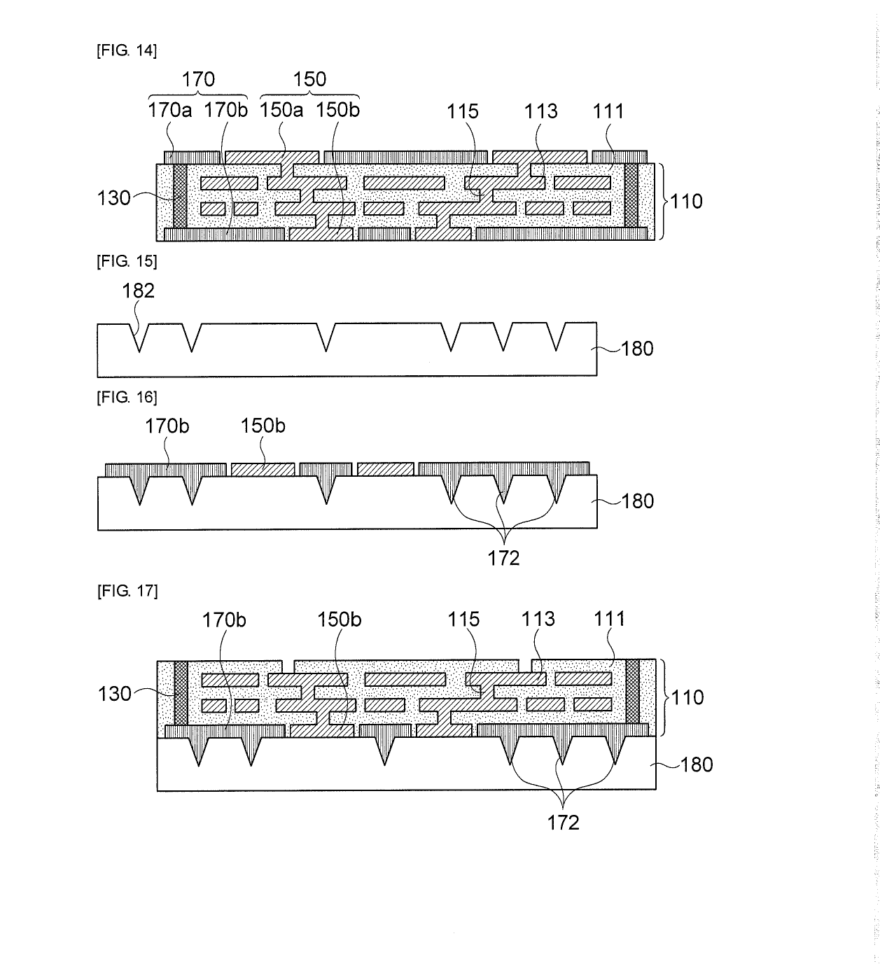

As in FIG. 13, the first dummy pattern 170a and the first circuit pattern 150a are formed on the substrate 110, and as in FIG. 14, the carrier 180 is removed so that the printed circuit board 100 in which the second dummy pattern 170b and the second circuit pattern 150b are embedded in the lower surface of the substrate 110 is completed.

Meanwhile, in the structure in which the dummy pattern 170 is embedded in at least one surface of the substrate 110, the dummy pattern 170 may have at least one projection 172. FIGS. 15 to 19 are cross-sectional views showing a process of forming the at least one projection on the dummy pattern. As in FIG. 15, the carrier 180 having at least one groove 182 on one surface thereof is provided.

After that, as in FIG. 16, the second dummy pattern 170b is formed in correspondence to the at least one groove 182, and the second circuit pattern 150b are formed on the carrier 180. That is, the second dummy pattern 170b is formed by performing plating inside the at least one groove 182 and on the groove 182.

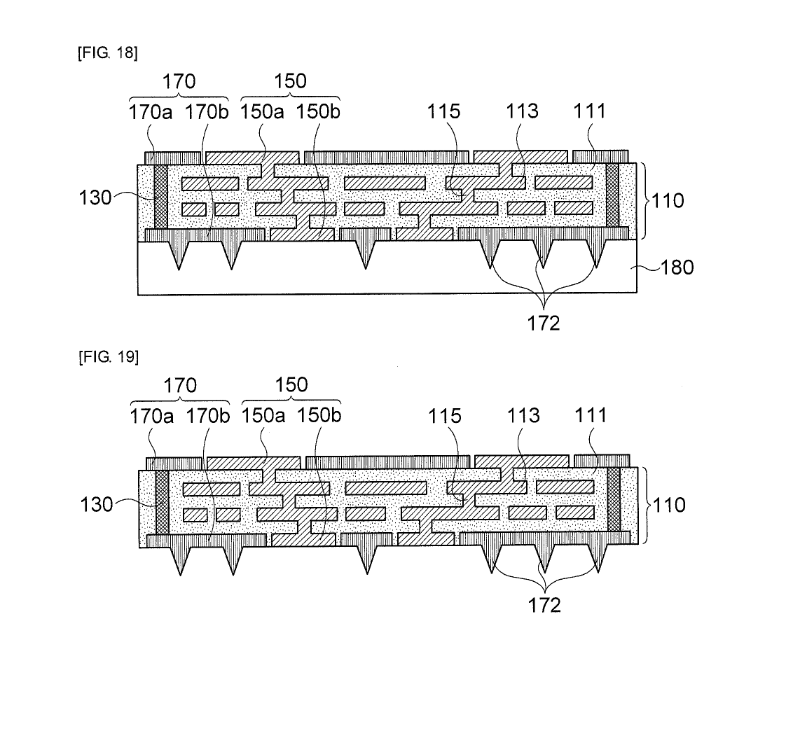

And, as in FIG. 17, the substrate 110 is formed on the second dummy pattern 170b and the second circuit pattern 150b, and as in FIG. 18, the first dummy pattern 170a and the first circuit pattern 150a are formed on the substrate 110.

Next, the at least one projection 172 is formed on the second dummy pattern 170b by removing the carrier 180. Here, the projection 172 may be formed in a shape protruding to the outside such as a cylinder or a cone.

Further, the projection 172 may be made of a metal material and have a structure in which an insulating material is filled inside and a metal material is formed on the insulating material with a predetermined thickness.

And, the projection 172 may be made of the same material as the dummy pattern 170 and integrally formed with the dummy pattern 170.

Like this, since the projection 172 is formed in a shape protruding to the outside to increase a surface area for radiating heat, there is an advantage that it is possible to effectively increase heat diffusion compared to the printed circuit board 100 shown in FIG. 1.

Further, when attaching different materials such as solder, since the projection 172 can provide a wide surface area, it can be also used as a terminal for connection with an external substrate.

As described above, in accordance with a printed circuit board and a method for manufacturing the same in accordance with an embodiment of the present invention, it is possible to suppress generation of electromagnetic waves or shield the electromagnetic waves and improve heat radiation characteristics at the same time by disposing a dummy pattern on a surface of a substrate on which a circuit pattern is not formed.

Further, since it is possible to reduce manufacturing costs and a thickness of the printed circuit board by employing a structure in which the dummy pattern is embedded in at least one surface of the substrate, it is possible to achieve miniaturization of electronic devices.

In addition, it is possible to effectively radiate heat by forming at least one projection in the embedded dummy pattern.

And, it is possible to suppress or shield electromagnetic waves generated from side surfaces of the substrate and improve heat radiation characteristics at the same time by forming a plurality of heat radiating vias along an outer edge of the substrate.

Due to this, it is possible to improve reliability of the entire electronic device in which the printed circuit board is installed.

The foregoing description illustrates the present invention. Additionally, the foregoing description shows and explains only the preferred embodiments of the present invention, but it is to be understood that the present invention is capable of use in various other combinations, modifications, and environments and is capable of changes and modifications within the scope of the inventive concept as expressed herein, commensurate with the above teachings and/or the skill or knowledge of the related art. The embodiments described hereinabove are further intended to explain best modes known of practicing the invention and to enable others skilled in the art to utilize the invention in such, or other, embodiments and with the various modifications required by the particular applications or uses of the invention. Accordingly, the description is not intended to limit the invention to the form disclosed herein. Also, it is intended that the appended claims be construed to include alternative embodiments.

What is claimed is:

1. A printed circuit board comprising:
a substrate;
a circuit pattern formed on a surface of the substrate;
a dummy pattern formed on the surface of the substrate, where the circuit pattern is not formed, to be spaced apart from the circuit pattern by a predetermined interval; and
a plurality of heat radiating vias formed along an outer edge of the substrate to electrically connect the dummy patterns through the substrate.

2. The printed circuit board according to claim 1, wherein the dummy pattern is embedded in at least one surface of the substrate.

3. The printed circuit board according to claim 1, wherein the plurality of heat radiating vias are formed to be overlapped with each other.

4. The printed circuit board according to claim 1, wherein the plurality of heat radiating vias are formed at intervals smaller than twice the diameter of the heat radiating via.

5. The printed circuit board according to claim 1, wherein the dummy pattern has at least one projection.

6. The printed circuit board according to claim 5, wherein the projection is made of the same material as the dummy pattern.

7. The printed circuit board according to claim 5, wherein the projection has a shape protruding to the outside.

8. The printed circuit board according to claim 5, wherein the projection is integrally formed with the dummy pattern.

9. The printed circuit board according to claim 5, wherein the projection has a structure in which an insulating material is filled inside and a metal material is formed on the insulating material.

10. The printed circuit board according to claim 2, wherein the surface in which the dummy pattern is embedded is a surface of the substrate on which an electronic component is mounted.

11. The printed circuit board according to claim 10, further comprising:
a solder resist layer formed on the surface in which the dummy pattern is not embedded.

12. The printed circuit board according to claim 10, wherein the solder resist layer is formed by printing a solder resist ink on the surface in which the dummy pattern is not embedded.

13. A method for manufacturing a printed circuit board comprising:
providing a substrate;
forming a circuit pattern on a surface of the substrate;
forming a dummy pattern on the surface of the substrate, where the circuit pattern is not formed, to be spaced apart from the circuit pattern by a predetermined interval; and
forming a plurality of heat radiating vias along an outer edge of the substrate to electrically connect the dummy patterns through the substrate.

14. The method for manufacturing a printed circuit board according to claim 13, wherein forming the dummy pattern forms the dummy pattern by embedding the dummy pattern in at least one surface of the substrate.

15. The method for manufacturing a printed circuit board according to claim 13, wherein the circuit pattern comprises first and second circuit patterns which are formed on upper and lower surfaces of the substrate, respectively, and the dummy pattern comprises first and second dummy patterns which are formed on the upper and lower surfaces of the substrate, respectively.

16. The method for manufacturing a printed circuit board according to claim 15, wherein forming the dummy pattern by embedding the dummy pattern in the at least one surface of the substrate comprises:
providing a carrier;
forming the second dummy pattern and the second circuit pattern on the carrier;
forming the substrate on the second dummy pattern and the second circuit pattern;
forming the first dummy pattern and the first circuit pattern on the substrate; and
removing the carrier.

17. The method for manufacturing a printed circuit board according to claim 15, wherein forming the dummy pattern by embedding the dummy pattern in the at least one surface of the substrate forms at least one projection on the dummy pattern.

18. The method for manufacturing a printed circuit board according to claim 17, wherein forming the at least one projection on the dummy pattern comprises:
providing the carrier having at least one groove formed on one surface thereof;
forming the second dummy pattern in correspondence to the at least one groove and forming the second circuit pattern on the carrier;
forming the substrate on the second dummy pattern and the second circuit pattern;
forming the first dummy pattern and the first circuit pattern on the substrate; and
removing the carrier.

19. The method for manufacturing a printed circuit board according to claim 13, wherein the plurality of heat radiating vias are formed to be overlapped with each other.

20. The method for manufacturing a printed circuit board according to claim 13, wherein the plurality of heat radiating vias are formed at intervals smaller than twice the diameter of the heat radiating via.

21. The method for manufacturing a printed circuit board according to claim 17, wherein the projection is made of the same material as the dummy pattern.

22. The method for manufacturing a printed circuit board according to claim 17, wherein the projection has a shape protruding to the outside.

23. The method for manufacturing a printed circuit board according to claim 17, wherein the projection is integrally formed with the dummy pattern.

24. The method for manufacturing a printed circuit board according to claim 17, wherein the projection has a structure in which an insulating material is filled inside and a metal material is formed on the insulating material.
